(19) United States
(12) Patent Application Publication
(10) Pub. No.: US 2024/0062592 A1
(43) Pub. Date: Feb. 22, 2024

(54) METHOD AND SYSTEM FOR PERFORMING A VIRTUAL TEST

(71) Applicant: dSPACE GmbH, Paderborn (DE)

(72) Inventors: Thomas MISCH, Paderborn (DE); Matthias WERTH, Paderborn (DE)

(73) Assignee: dSPACE GmbH, Paderborn (DE)

(21) Appl. No.: 18/216,924

(22) Filed: Jun. 30, 2023

(30) Foreign Application Priority Data
Aug. 17, 2022 (DE) 10 2022 120 754.4

(51) Int. Cl. G07C 5/06; G06F 30/20

(52) U.S. Cl. CPC G07C 5/06; G06F 30/20; B60W 50/045

(57) ABSTRACT

A method and system for performing a virtual test of a device for the at least partial autonomous guidance of a motor vehicle, comprising performing the virtual test by an algorithm using the at least one parameter set of driving situation parameters, wherein the virtual test performed by the algorithm simulates the at least one parameter set of driving situation parameters; and, if a predetermined condition and/or a condition determined by the algorithm is fulfilled, changing the at least one first parameter, detected by the at least one vehicle sensor and/or a third parameter relating to a vehicle actuator during a runtime of the virtual test.

This nonprovisional application claims priority under 35 U.S.C. § 119(a) to German Patent Application No. 10 2022 120 754.4, which was filed in Germany on Aug. 17, 2022, and which is herein incorporated by reference.

### BACKGROUND OF THE INVENTION

### Field of the Invention

The present invention relates to a computer-implemented method for performing a virtual test of a device for the at least partial autonomous guidance of a motor vehicle. The present invention further relates to a system for performing a virtual test of a device for the at least partial autonomous guidance of a motor vehicle. Moreover, the invention relates to a computer program with a program code to carry out the method of the invention.

### Description of the Background Art

Driving assistance systems, i.e., devices for the at least partial autonomous guidance of a motor vehicle, such as, e.g., an adaptive cruise control and/or functions for highly automated driving can be verified or validated using various verification methods. In this regard, simulations can be used in particular.

Traditionally, an algorithm performing the virtual test, in particular an ITC algorithm, is able to identify specific test cases of interest within a given parameter space.

The test execution occurs in this case on the assumption that all of the vehicle's environmental and vehicle data are provided using properly functioning sensors and detection components, so that the data generated accurately represent the vehicle's driving situation.

However, if, for example, a sensor or a detection component and/or an actuator were to have a malfunction or a limited performance in the real driving operation, an algorithm processing the sensor data will deliver erroneous output data, which in turn can lead to faulty control of the corresponding actuator systems.

Consequently, there is a need to improve existing test procedures for driving assistance systems so that the algorithm processing the sensor data avoids the output of erroneous output data for controlling the corresponding actuator systems even in the case of erroneous input data generated by sensors having a malfunction or limited performance.

### SUMMARY OF THE INVENTION

It is therefore an object of the present invention to provide a method for performing a virtual test of a device for the at least partial autonomous guidance of a motor vehicle, which avoids the outputting of erroneous output data for controlling corresponding actuator systems even in the case of erroneous input data generated by sensors having a malfunction or limited performance.

According to an exemplary embodiment of the invention, the object can be achieved by a computer-implemented method for performing a virtual test of a device for the at least partial autonomous guidance of a motor vehicle. The object is further achieved by a system for performing a virtual test of a device for the at least partial autonomous guidance of a motor vehicle. Also, the object is further achieved by a computer program with a program code to carry out the method of the invention.

Thus, the invention relates to a computer-implemented method for performing a virtual test of a device for the at least partial autonomous guidance of a motor vehicle.

The method comprises providing at least one parameter set of driving situation parameters, wherein the driving situation parameters comprise at least one first parameter, detected by at least one vehicle sensor, and at least one second parameter, representing at least one further scenario object.

Furthermore, the method comprises performing the virtual test by an algorithm using the at least one parameter set of driving situation parameters, wherein the virtual test performed by the algorithm simulates the at least one parameter set of driving situation parameters.

The invention further comprises monitoring at least one driving situation parameter of the parameter set of driving situation parameters, and if a predetermined condition and/or a condition determined by the algorithm is fulfilled, changing the at least one first parameter, detected by the at least one vehicle sensor, and/or a third parameter, relating to a vehicle actuator, during a runtime of the virtual test.

The invention further relates to a system for performing a virtual test of a device for the at least partial autonomous guidance of a motor vehicle.

The system comprises a data memory, which can be set up to provide at least one parameter set of driving situation parameters, wherein the driving situation parameters comprise at least one first parameter, detected by at least one vehicle sensor, and at least one second parameter, representing at least one further scenario object.

Moreover, the system comprises a computing device that is set up to perform the virtual test by an algorithm using the at least one parameter set of driving situation parameters, wherein the virtual test performed by the algorithm simulates the at least one parameter set of driving situation parameters, wherein the computing device is set up to monitor at least one driving situation parameter of the parameter set of driving situation parameters, and wherein the computing device is further set up to change the at least one first parameter, detected by the at least one vehicle sensor, and/or a third parameter, relating to a vehicle actuator, during a runtime of the virtual test if a predetermined condition and/or a condition determined by the algorithm is fulfilled. The computing device can be, for example, a computer, networked computers, a vehicle electronic control unit (ECU), etc.

The invention further relates to a computer program with a program code to carry out the method of the invention when the computer program is executed on a computer.

In this context, the further scenario object refers, for example, to a further object, such as a vehicle, a pedestrian, or a stationary object, apart from an ego or test vehicle comprising the at least one vehicle sensor.

In general the term “ego vehicle” can represent a virtual vehicle in the center of a simulation or a test. E.g. the vehicle for that a new function is to be developed or tested. Typically, one skilled in the art uses such to distinguish a central vehicle (“ego”) from other vehicles or traffic participants (pedestrians, bicycles, etc.) that are usually called “fellows” or “fellow vehicles” that appear in a simulation or test and can interact or have an impact on the ego. For example, there may be several vehicles in a scenario in order to test a function of the ego vehicle but these fellow vehicles may not have the function to be tested, e.g. automatic braking systems.

The parameter set of driving situation parameters here can comprise sensor data or sensor signals from vehicle sensors.

The virtual test of the at least one parameter set of driving situation parameters comprises a scenario or test scenario having a plurality of scenario objects.

The scenario on which the virtual test is based can be determined, on the one hand, by driving situation parameters or environmental parameters, or, on the other hand, can be a logical scenario which itself comprises or represents a plurality of scenarios.

Further, the scenario can be formed by a data replay scenario, for example, in which only previously recorded driving situations are replayed for the test.

An idea of the present invention is to be able to test a malfunction of the sensor and/or of the actuator as well as a behavior of a control unit under test and/or of a driver assistance function for the malfunction of the sensor and/or of the actuator by changing the at least one first parameter, detected by the at least one vehicle sensor, and/or the third parameter, relating to the vehicle actuator, during a runtime of the virtual test.

Thus, a focusing of virtual tests on necessary or meaningful error simulations can be increased as well as a number of unnecessary, repetitive, or not meaningful tests can be significantly reduced, which results in an efficiency gain. Further, tests or test situations can also be carried out that a tester might have overlooked manually.

New test runs can therefore be started by changing or writing the variable. The method of the invention thus tests a reaction of the system or of the underlying driver assistance function in the scenario to the introduced fault condition. Thus, based on the virtual tests, a control unit software carrying out the driver assistance function in question can be continuously improved.

The predetermined condition and/or the condition determined by the algorithm can be fulfilled if at least one of the provided driving situation parameters and/or an indicator representing a plurality of driving situation parameters lies outside a predetermined value range and/or a value range determined by the algorithm.

Thus, a predefined criterion is available, which can be used to start a new test process, in which a defined error state of a sensor and/or actuator is tested in the given scenario.

Values lying outside the predetermined value range and/or the value range determined by the algorithm can represent a safety-critical driving situation, in particular that a longitudinal and/or lateral distance of an ego vehicle from a fellow vehicle is less than or equal to a predetermined threshold value.

Thus, especially in safety-critical driving situations, a malfunction and/or failure of at least one vehicle sensor and/or vehicle actuator can be additionally tested.

The driving situation parameter values which lie outside the predetermined value range and/or the value range determined by the algorithm and which represent the safety-critical driving situation can lie within a parameter space. The parameter space thus maps driving situation parameters of interest, which relate in particular to safety-critical driving situations.

The algorithm can determine the test cases representing the safety-critical driving situation within the parameter space. The algorithm is thus able to automatically identify safety-critical driving situations of interest in the specified parameter space, based on which faulty sensors and/or actuators can then be tested.

Changing the at least one first parameter, detected by the at least one vehicle sensor, and/or the third parameter, relating to the vehicle actuator, during the runtime of the virtual test can represent generating a failure and/or a malfunction of the at least one vehicle sensor and/or the at least one vehicle actuator.

Changing the parameter therefore has the same effect as when a vehicle sensor generates erroneous data, for example.

Generating the failure and/or the malfunction of the at least one vehicle sensor and/or of the at least one vehicle actuator can comprise an interruption of a communication link between a control unit and the vehicle sensor and/or vehicle actuator, an interruption of a power supply of the vehicle sensor and/or vehicle actuator, and a limitation of a performance of the vehicle sensor, in particular due to a contamination of the vehicle sensor.

Thus, a wide variety of different fault conditions or malfunctions of vehicle sensors and/or vehicle actuators can be tested in an advantageous manner.

The algorithm can determine variable values for generating the failure and/or a malfunction of the at least one vehicle sensor and/or the at least one vehicle actuator.

The algorithm is thus advantageously able to determine a type as well as a degree of the tested sensor or actuator malfunction.

The algorithm can generate contradictory data, in particular mutually inconsistent data, for redundant and/or different vehicle sensors. The system or the underlying driver assistance function can thus be tested in a scenario in which, for example, identical sensors generate different data with respect to the same scene.

Changing the at least one first parameter, detected by the at least one vehicle sensor, and/or the third parameter, relating to the vehicle actuator, during the runtime of the virtual test comprises writing a variable representing the at least one driving situation parameter. Writing the variable thus enables the introduction of a fault condition of a vehicle sensor and/or vehicle actuator into the scenario under test.

The vehicle sensor can be, for example, a camera sensor, a radar sensor, a LiDAR sensor, an ultrasonic sensor, an infrared sensor, a tire pressure sensor, a wheel speed sensor, and/or a GNSS sensor, in particular a GPS sensor, and wherein the vehicle actuator is an adaptive cruise control, a lane departure warning system, an active brake assist, and/or a parking assist. Thus, malfunctions and/or failure of a wide variety of different sensor types as well as actuator types can be tested.

The first parameter, detected by the vehicle sensor, may be a vehicle speed of an ego vehicle, a distance of the ego vehicle to a fellow vehicle driving ahead or behind, and/or an acceleration or deceleration of the ego vehicle and/or a fellow vehicle.

A critical driving situation can thus be defined based on the first parameter using a corresponding value range.

The at least one second parameter, representing at least one further scenario object, can be a lane width, a road course, traffic signs, road users, buildings, and/or vegetation.

The second parameter, in combination with the first parameter, thus contributes to the determination of critical driving situations, on the basis of which the malfunction or failure of sensors and/or actuators can be tested.

The features of the method as they are described herein for performing a virtual test of a device for the at least partial autonomous guidance of a motor vehicle are equally applicable to the system of the invention for performing a virtual test of a device for the at least partial autonomous guidance of a motor vehicle and vice versa.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a flowchart of a method for performing a virtual test of a device for the at least partial autonomous guidance of a motor vehicle according to a preferred embodiment of the invention; and

FIG. 2 shows a schematic representation of a system for performing a virtual test of a device for the at least partial autonomous guidance of a motor vehicle according to the preferred embodiment of the invention.

### DETAILED DESCRIPTION

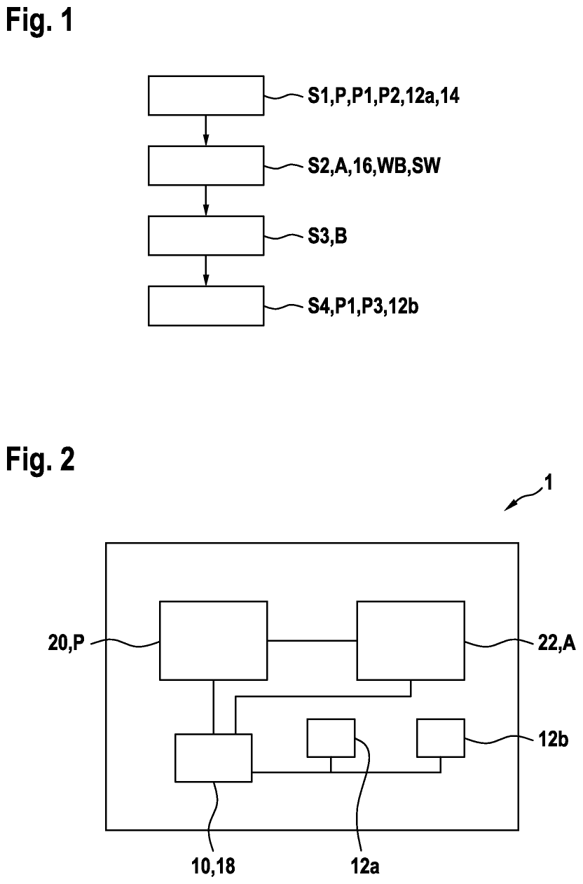

The method shown in FIG. 1 comprises providing 51 at least one parameter set P of driving situation parameters, wherein the driving situation parameters comprise at least one first parameter P1, detected by at least one vehicle sensor 12a, and at least one second parameter P2, representing at least one further scenario object 14.

The method further comprises performing S2 the virtual test by an algorithm A using the at least one parameter set P of driving situation parameters, wherein the virtual test performed by the algorithm A simulates the at least one parameter set P of driving situation parameters.

The invention further comprises monitoring S3 at least one driving situation parameter of the parameter set P of driving situation parameters, and if a predetermined condition B and/or a condition B determined by the algorithm A is fulfilled, changing S4 the at least one first parameter P1, detected by the at least one vehicle sensor 12a, and/or a third parameter P3, relating to a vehicle actuator 12b, during a runtime of the virtual test.

The predetermined condition B and/or the condition B determined by the algorithm A is fulfilled if at least one of the provided driving situation parameters and/or an indicator 16 representing a plurality of driving situation parameters lies outside a predetermined value range WB and/or a value range WB determined by the algorithm A.

Values lying outside the predetermined value range WB and/or value range WB determined by the algorithm A here represent a safety-critical driving situation, in particular that a longitudinal and/or lateral distance of an ego vehicle from a fellow vehicle is less than or equal to a predetermined threshold value SW.

The values of the driving situation parameters which lie outside the predetermined value range WB and/or the value range WB determined by the algorithm A and which represent the safety-critical driving situation lie within a parameter space.

The algorithm A determines the test cases representing the safety-critical driving situation within the parameter space.

Changing S4 the at least one first parameter P1, detected by the at least one vehicle sensor 12a, and/or the third parameter P3, relating to vehicle actuator 12b, during the runtime of the virtual test here represents generating a failure and/or a malfunction of the at least one vehicle sensor 12a and/or the at least one vehicle actuator.

Generating the failure and/or malfunction of the at least one vehicle sensor 12a and/or of the at least one vehicle actuator comprises an interruption of a communication link between a control unit 18 and vehicle sensor 12a and/or vehicle actuator 12b, an interruption of a power supply to vehicle sensor 12a and/or the vehicle actuator, and a limitation of a performance of vehicle sensor 12a, in particular due to a contamination of vehicle sensor 12a.

The algorithm A determines variable values for generating the failure and/or malfunction of the at least one vehicle sensor 12a and/or the at least one vehicle actuator. The algorithm A further generates contradictory data, in particular mutually inconsistent data, for redundant and/or different vehicle sensors 12a.

Changing S4 the at least one first parameter P1, detected by the at least one vehicle sensor 12a, and/or the third parameter P3, relating to vehicle actuator 12b, during the runtime of the virtual test thereby comprises writing a variable representing the at least one driving situation parameter.

Vehicle sensor 12a is preferably a camera sensor, a radar sensor, a LiDAR sensor, an ultrasonic sensor, or an infrared sensor.

Alternatively, vehicle sensor 12a can be, for example, a tire pressure sensor, a wheel speed sensor, and/or a GNSS sensor, particularly a GPS sensor. Vehicle actuator 12b is, for example, an adaptive cruise control, a lane departure warning system, an active brake assistant, and/or a parking assistant.

The first parameter P1, detected by vehicle sensor 12a, can be, for example, a vehicle speed of an ego vehicle, a distance of the ego vehicle to a fellow vehicle driving ahead or behind, and/or an acceleration or deceleration of the ego vehicle and/or a fellow vehicle.

The at least one second parameter P2, representing at least one further scenario object 14, is, for example, a lane width, a road course, traffic signs, road users, buildings, and/or vegetation.

FIG. 2 shows a schematic representation of a system 1 for performing a virtual test of a device 10 for the at least partial autonomous guidance of a motor vehicle according to the preferred embodiment of the invention.

System 1 comprises a data memory 20, which is set up to provide at least one parameter set P of driving situation parameters, wherein the driving situation parameters comprise at least one first parameter P1, detected by at least one vehicle sensor 12a, and at least one second parameter P2, representing at least one further scenario object 14.

Furthermore, system 1 includes a computing device 22 that is set up to perform the virtual test by an algorithm A using the at least one parameter set P of driving situation parameters, wherein the virtual test performed by the algorithm A simulates the at least one parameter set P of driving situation parameters, wherein computing device 22 is set up further to monitor at least one driving situation parameter of the parameter set P of driving situation parameters, and wherein computing device 22 is further set up to change the at least one first parameter P1, detected by the at least one vehicle sensor 12a, and/or a third parameter P3, relating to a vehicle actuator 12b, during a runtime of the virtual test if a predetermined condition B and/or a condition B determined by the algorithm A is fulfilled.

Although specific embodiments have been illustrated and described herein, it will be understood by the skilled artisan that there are a wide variety of alternative and/or equivalent implementations. It should be noted that the exemplary embodiment or exemplary embodiments are examples only and are not intended to restrict the scope, applicability, or configuration in any way.

Rather, the foregoing summary and detailed description provides the skilled artisan with convenient instructions for implementing at least one exemplary embodiment, wherein it is understood that various changes in the functional scope and arrangement of the elements can be made without departing from the scope of the appended claims and their legal equivalents.

In general, this application intends to cover modifications or adaptations or variations of the embodiments disclosed herein. For example, a sequence of the method steps can be changed. The method can further be carried out sequentially or in parallel, at least in sections.

What is claimed is:

1. A computer-implemented method for performing a virtual test of a device for the at least partial autonomous guidance of a motor vehicle, the method comprising:
providing at least one parameter set of driving situation parameters, the driving situation parameters comprising at least one first parameter detected by at least one vehicle sensor, and comprising at least one second parameter representing at least one further scenario object;
performing the virtual test by an algorithm using the at least one parameter set of driving situation parameters, the virtual test performed by the algorithm simulating the at least one parameter set of driving situation parameters;
monitoring at least one driving situation parameter of the parameter set of driving situation parameters; and
if a predetermined condition and/or a condition determined by the algorithm is fulfilled, changing the at least one first parameter detected by the at least one vehicle sensor and/or a third parameter relating to a vehicle actuator during a runtime of the virtual test.

2. The computer-implemented method according to claim 1, wherein the predetermined condition and/or the condition determined by the algorithm is fulfilled if at least one of the provided driving situation parameters and/or an indicator representing a plurality of driving situation parameters lies outside a predetermined value range and/or a value range determined by the algorithm.

3. The computer-implemented method according to claim 2, wherein values lying outside the predetermined value range and/or the value range determined by the algorithm represent a safety-critical driving situation or that a longitudinal and/or lateral distance of an ego vehicle from a fellow vehicle is less than or equal to a predetermined threshold value.

4. The computer-implemented method according to claim 3, wherein the driving situation parameter values which lie outside the predetermined value range and/or a value range determined by the algorithm and which represent the safety-critical driving situation lie within a parameter space.

5. The computer-implemented method according to claim 4, wherein the algorithm determines test cases representing the safety-critical driving situation within the parameter space.

6. The computer-implemented method according to claim 1, wherein changing the at least one first parameter, detected by the at least one vehicle sensor, and/or the third parameter relating to the vehicle actuator during the runtime of the virtual test represents generating a failure and/or a malfunction of the at least one vehicle sensor and/or the at least one vehicle actuator.

7. The computer-implemented method according to claim 6, wherein generating the failure and/or the malfunction of the at least one vehicle sensor and/or of the at least one vehicle actuator comprises an interruption of a communication link between a control unit and the vehicle sensor and/or vehicle actuator, an interruption of a power supply of the vehicle sensor and/or vehicle actuator, and a limitation of a performance of the vehicle sensor due to a contamination of the vehicle sensor.

8. The computer-implemented method according to claim 6, wherein the algorithm determines variable values for generating the failure and/or a malfunction of the at least one vehicle sensor and/or the at least one vehicle actuator.

9. The computer-implemented method according to claim 1, wherein the algorithm generates contradictory data or mutually inconsistent data for redundant and/or different vehicle sensors.

10. The computer-implemented method according to claim 1, wherein changing the at least one first parameter, detected by the at least one vehicle sensor, and/or the third parameter relating to the vehicle actuator during the runtime of the virtual test comprises writing a variable representing the at least one driving situation parameter.

11. The computer-implemented method according to claim 1, wherein the vehicle sensor is a camera sensor, a radar sensor, a LiDAR sensor, an ultrasonic sensor, an infrared sensor, a tire pressure sensor, a wheel speed sensor, and/or a GNSS sensor or a GPS sensor, and wherein the vehicle actuator is an adaptive cruise control, a lane departure warning system, an active brake assist, and/or a parking assist.

12. The computer-implemented method according claim 1, wherein the first parameter detected by the vehicle sensor is a vehicle speed of an ego vehicle, a distance of the ego vehicle to a fellow vehicle driving ahead or behind, and/or an acceleration or deceleration of the ego vehicle and/or a fellow vehicle.

13. The computer-implemented method according to claim 1, wherein the at least one second parameter representing at least one further scenario object is a lane width, a road course, traffic signs, road users, buildings, and/or vegetation.

14. A system for performing a virtual test of a device for the at least partial autonomous guidance of a motor vehicle, the system comprising:
a data memory, which is set up to provide at least one parameter set of driving situation parameters, the driving situation parameters comprising at least one first parameter detected by at least one vehicle sensor and comprising at least one second parameter representing at least one further scenario object; and
a computing device that is set up to perform the virtual test by an algorithm using the at least one parameter set of driving situation parameters, the virtual test performed by the algorithm simulating the at least one parameter set of driving situation parameters, the computing device being further set up to monitor at least one driving situation parameter of the parameter set of driving situation parameters and further set up to change the at least one first parameter detected by the at least one vehicle sensor and/or a third parameter relating to a vehicle actuator during a runtime of the virtual test if a predetermined condition and/or a condition determined by the algorithm is fulfilled.

15. A computer program with a program code to carry out the method of claim 1, when the computer program is executed on a computer.
